(19) United States
(12) Patent Application Publication
(10) Pub. No.: US 2010/0127292 A1
(43) Pub. Date: May 27, 2010

(54) Wafer level led package structure for increasing light-emitting efficiency and method for making the same

(76) Inventors: Bily Wang, Hsinchu City (TW); Sung-Yi Hsiao, Gongguan Shiang (TW); Jack Chen, Toufen Township (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/461,742

(22) Filed: Aug. 24, 2009

(30) Foreign Application Priority Data
Nov. 24, 2008 (TW) 97145305

(51) Int. Cl. H01L 33/00; H01L 21/30

(52) U.S. Cl. 257/98; 438/27; 257/E33.067; 257/E21.211

(57) ABSTRACT

A wafer level LED package structure for increasing light-emitting efficiency includes: a light-emitting unit, an insulating unit, two first conductive units and two second conductive units. The light-emitting unit has a light-emitting body, a positive conductive layer, a negative conductive layer, and a reflecting insulating layer formed between the positive conductive layer and the negative conductive layer. The light-emitting body has a bottom material layer and a top material layer. The insulating unit is formed around an outer area of a top surface of the bottom material layer and formed on a top surface of the reflecting insulating layer. One first conductive unit is formed on one part of the positive conductive layer and the insulating unit, and another first conductive unit is formed on one part of the negative conductive layer and the insulating unit. The two second conductive units are respectively formed on the two first conductive units.

### BACKGROUND OF THE INVENTION

1. Field of the Invention

The present invention relates to a wafer level LED package structure and a method for making the same, and particularly relates to a wafer level LED package structure for increasing light-emitting efficiency and a method for making the same.

2. Description of Related Art

Referring to FIG. 1, the prior art provides an LED (Light Emitting Diode) package structure including: a light-emitting body 1, a positive conductive layer P and a negative conductive layer N formed on the light-emitting body 1, a dielectric layer R formed between the positive conductive layer P and the negative conductive layer N, a reflecting layer 2 formed on a bottom side of the light-emitting body 1 and a transparent package body 3 for covering the light-emitting body 1.

Moreover, the LED package structure is electrically disposed on a PCB (Printed Circuit Board). The positive conductive layer P and the negative conductive N are electrically connected to the PCB via two wires w. One part of light beam generated from the light-emitting body 1 is directed upward, and another part of the light beams L generated from the light-generating body 1 is projected downwards and is reflected by the reflecting layer 2 in order to generate upward projecting light.

In normal state, the currents of the positive GaN conductive layer GaN—P flow downwards as the downward arrows shown in FIG. 1, so that light beams are generated from the contact face between the positive GaN conductive layer GaN—P and the negative GaN conductive layer GaN—N. However, the thickness of the dielectric layer R is over thin, a short circuit occurs easily between the lateral side of the positive GaN conductive layer GaN—P and the negative GaN conductive layer GaN—N as the inclined arrow shown in FIG. 1. Therefore, the LED package structure of the prior art will loss the light-emitting function easily.

### SUMMARY OF THE INVENTION

One particular aspect of the present invention is to provide a wafer level LED package structure for increasing light-emitting efficiency and a method for making the same. The present invention uses an insulating unit in order to increase the thickness of a reflecting insulating layer, so that the short circuit does not occur easily between the lateral side of the positive GaN conductive layer and the negative GaN conductive layer.

In order to achieve the above-mentioned aspects, the present invention provides a wafer level LED package structure for increasing light-emitting efficiency, including: a light-emitting unit, an insulating unit, at least two first conductive units and at least two second conductive units. The light-emitting unit has a light-emitting body, a positive conductive layer and a negative conductive layer formed on the light-emitting body, a reflecting insulating layer formed between the positive conductive layer and the negative conductive layer, and a light-emitting area formed in the light-emitting body. The light-emitting body has a bottom material layer and a top material layer formed on the bottom material layer. The insulating unit is formed around an outer area of a top surface of the bottom material layer and formed on a top surface of the reflecting insulating layer. One first conductive unit is formed on one part of the positive conductive layer and on one part of the insulating unit, and another first conductive unit is formed on one part of the negative conductive layer and on one part of the insulating unit. The two second conductive units are respectively formed on the two first conductive units.

In order to achieve the above-mentioned aspects, the present invention provides a method for making a wafer level LED package structure for increasing light-emitting efficiency, including: providing a wafer having a plurality of light-emitting units, each light-emitting unit having a light-emitting body, a positive conductive layer and a negative conductive layer formed on the light-emitting body, a reflecting insulating layer formed between the positive conductive layer and the negative conductive layer, and a light-emitting area formed in the light-emitting body, and the light-emitting body having a bottom material layer and a top material layer formed on the bottom material layer; removing a peripheral part of the top material layer in order to expose an outer area of a top surface of the bottom material layer; and then forming an insulating layer on the light-emitting units.

The method further includes: removing one part of the insulating layer to form an insulating unit, the insulating unit having at least two first openings for exposing one part of the positive conductive layer and one part of the negative conductive layer, and the insulating unit being formed around the outer area of the top surface of the bottom material layer and formed on a top surface of the reflecting insulating layer; forming a first conductive layer in order to fill the two first openings and cover the insulating unit; forming a photoresistant layer on the first conductive layer; removing one part of the photoresistant layer to form at least two second openings that are respectively formed above the positive conductive layer and the negative conductive layer; respectively filling at least two second conductive layers into the two second openings in order to form at least two second conductive units; and then removing other photoresistant layer and one part of the first conductive layer that is under the other photoresistant layer, in order to form two first conductive units.

Hence, the present invention has the following advantages: the short circuit does not occur easily between the lateral side of the positive GaN conductive layer and the negative GaN conductive layer due to the thickness insulating unit, so that the wafer level LED package structure of the present invention can generate light beams normally.

It is to be understood that both the foregoing general description and the following detailed description are exemplary, and are intended to provide further explanation of the invention as claimed. Other advantages and features of the invention will be apparent from the following description, drawings and claims.

### BRIEF DESCRIPTION OF THE DRAWINGS

The various objectives and advantages of the present invention will be more readily understood from the following detailed description when read in conjunction with the appended drawings, in which:

FIG. 1 is a lateral, schematic view of an LED package structure of the prior art;

FIG. 2 is a flowchart of a method for making a wafer level LED package structure for increasing light-emitting efficiency according to the first embodiment of the present invention;

FIGS. 2A to 2K are lateral, schematic views of a wafer level LED package structure for increasing light-emitting efficiency according to the first embodiment of the present invention, at different stages of the packaging processes, respectively;

FIG. 2L is a lateral, schematic view of a wafer level LED package structure electrically disposed on a PCB via solder glue according to the first embodiment of the present invention;

FIG. 3 is a partial flowchart of a method for making a wafer level LED package structure for increasing light-emitting efficiency according to the second embodiment of the present invention;

FIGS. 3A to 3C are lateral, schematic views of a wafer level LED package structure for increasing light-emitting efficiency according to the second embodiment of the present invention, at different stages of the partial packaging processes, respectively; and

FIG. 3D is a lateral, schematic view of a wafer level LED package structure electrically disposed on a PCB via solder glue according to the second embodiment of the present invention.

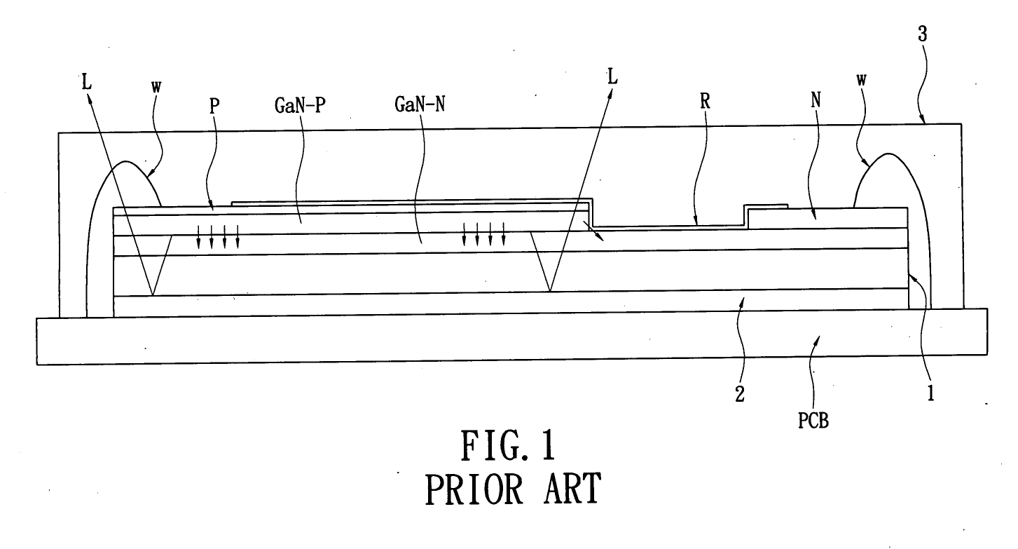

### DETAILED DESCRIPTION OF THE PREFERRED EMBODIMENTS

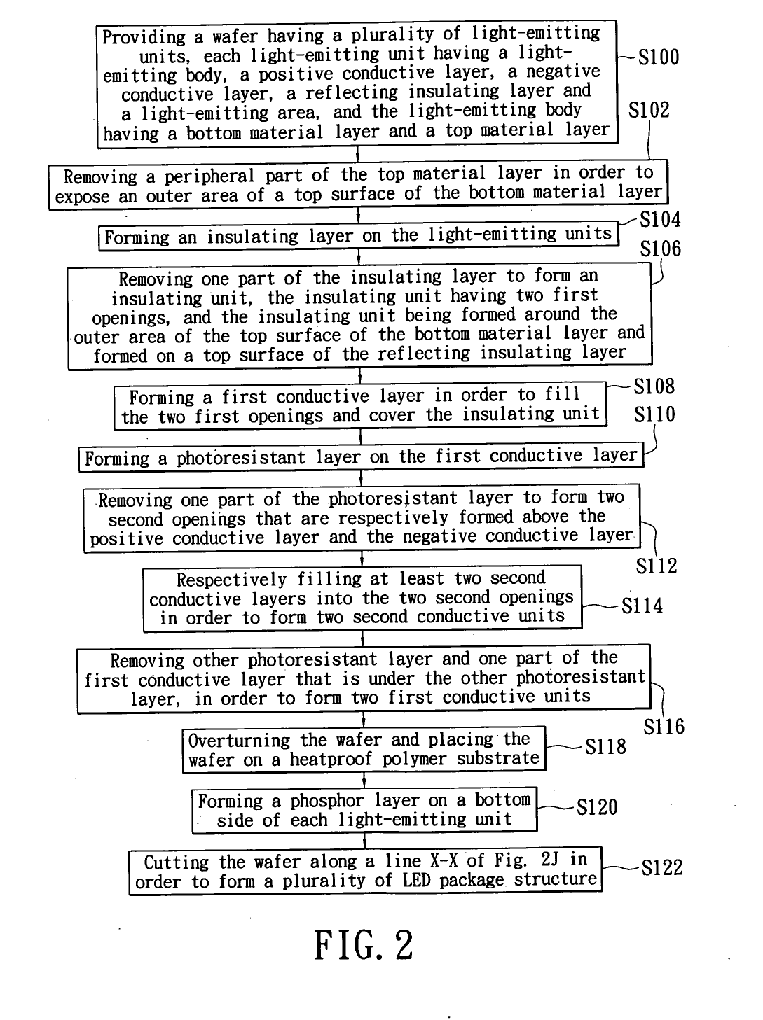

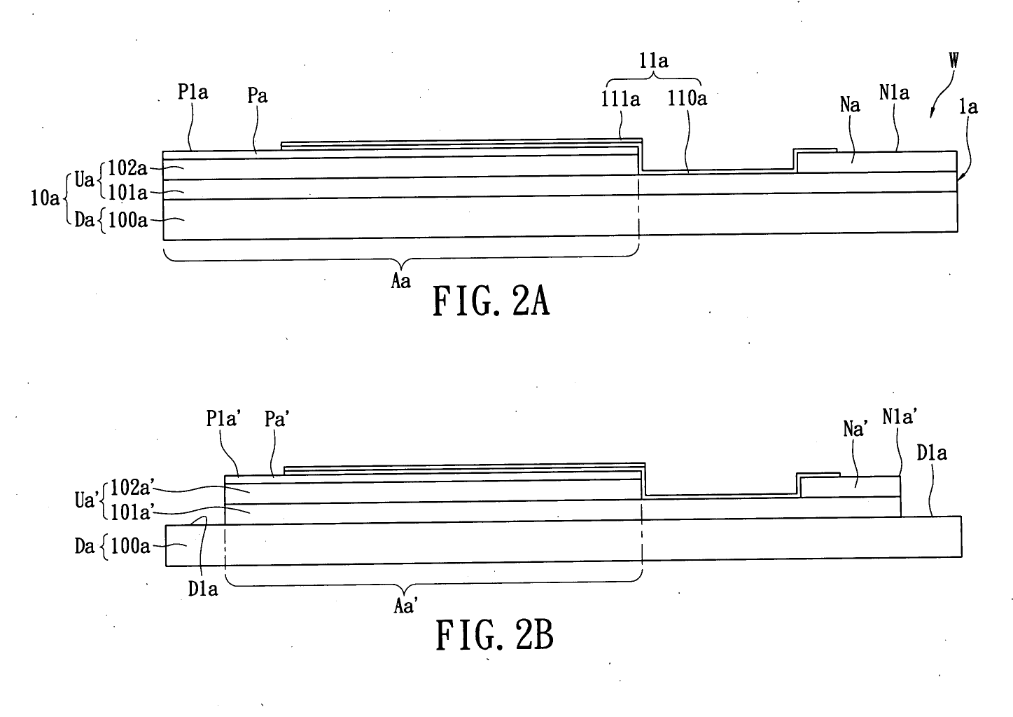

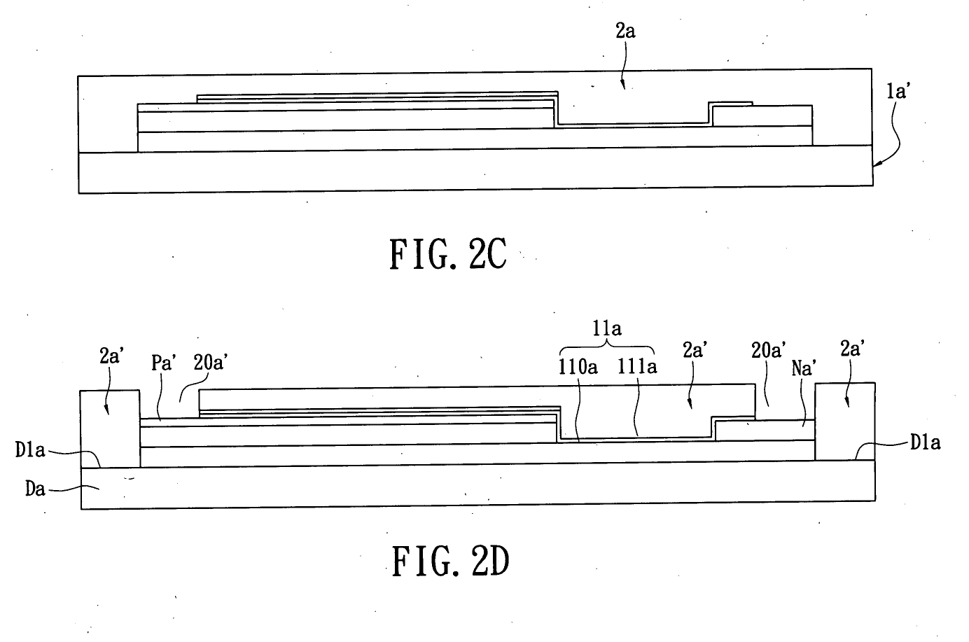

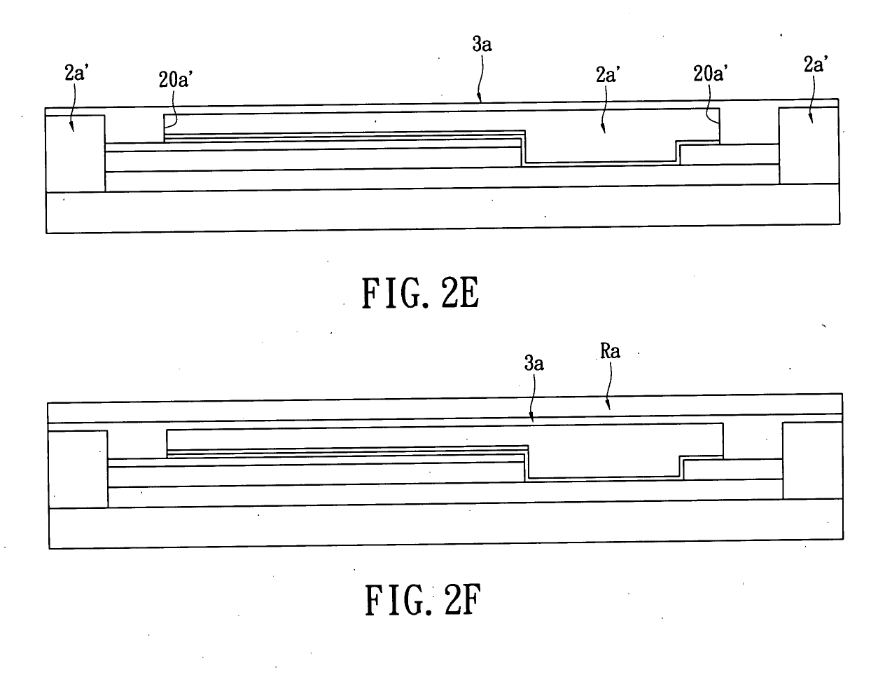

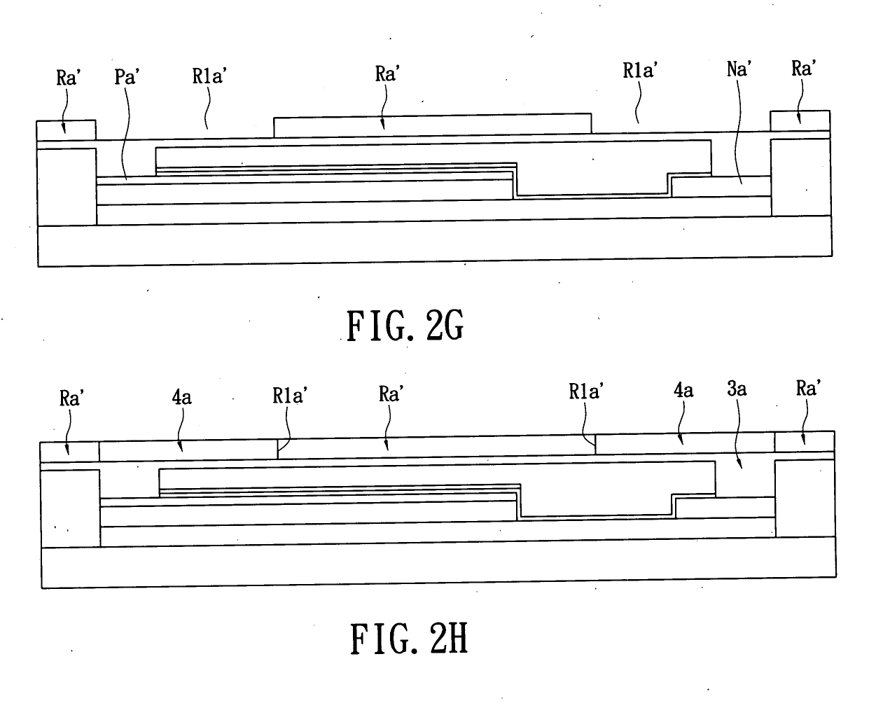

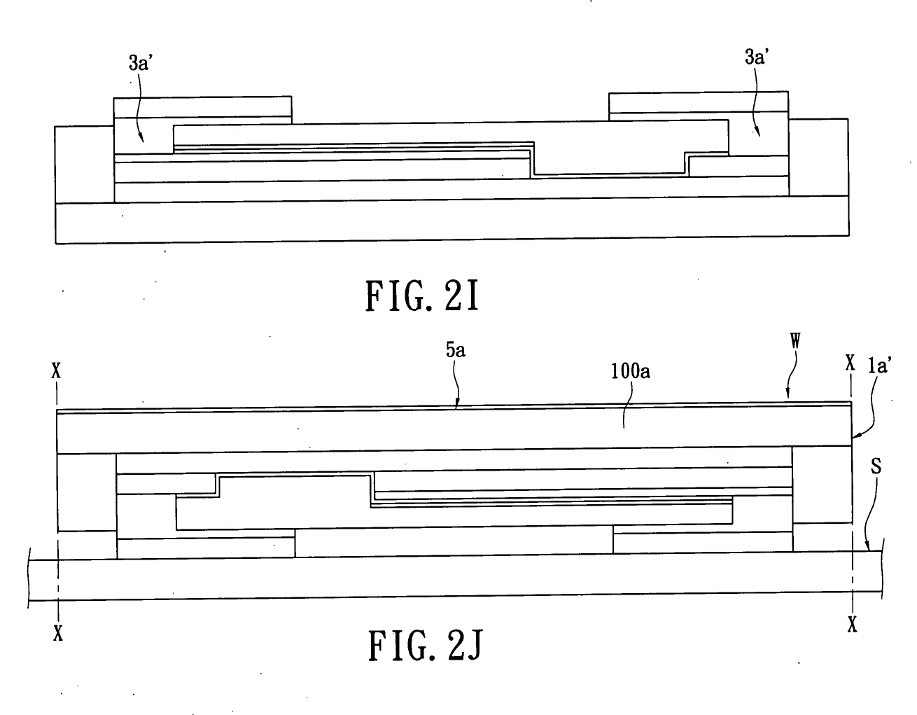

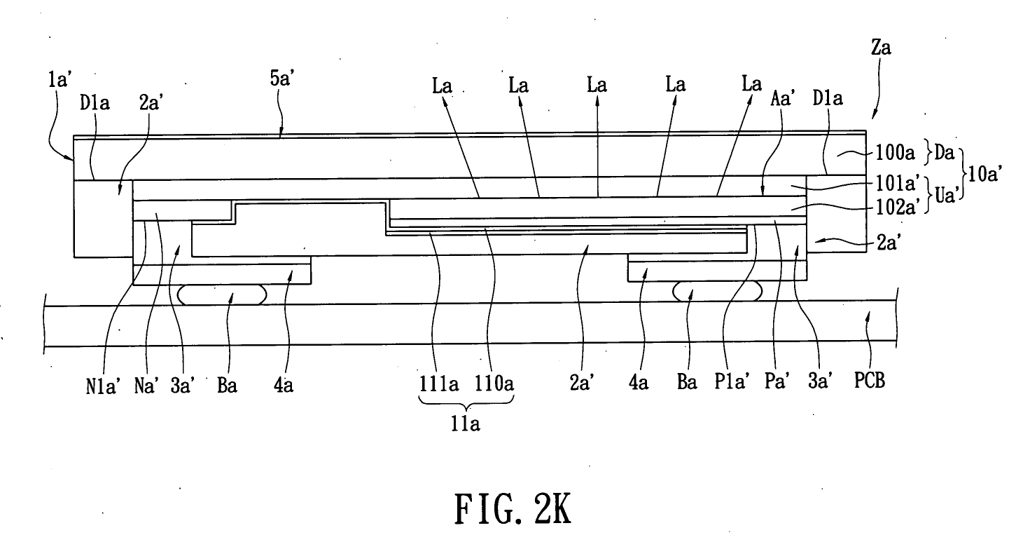

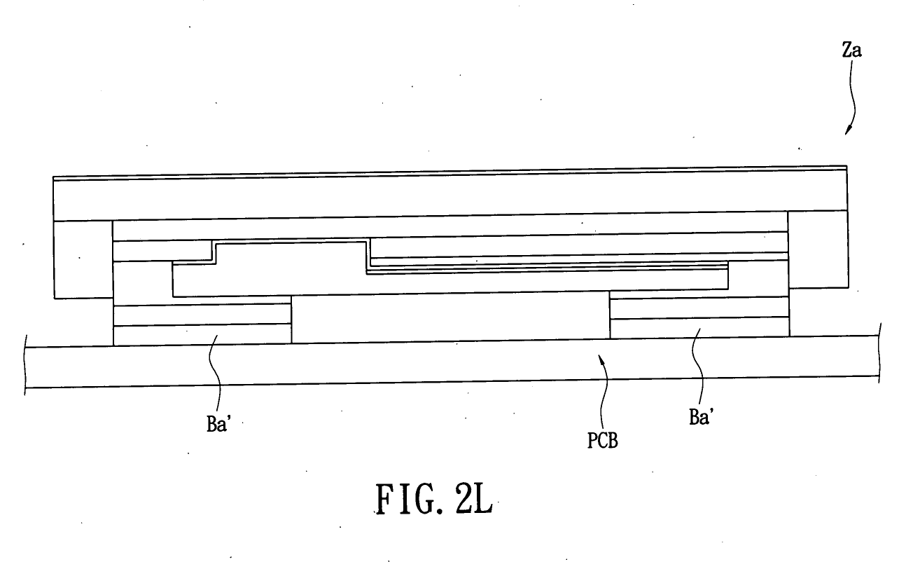

Referring to FIGS. 2 and 2A to 2K, the first embodiment of the present invention provides a method for making a wafer level LED package structure for increasing light-emitting efficiency. The method includes following steps:

The step S100 is: referring to FIGS. 2 and 2A, providing a wafer W having a plurality of light-emitting units 1a (only shown one light-emitting units 1a in Figures), each light-emitting unit 1a having a light-emitting body 10a, a positive conductive layer Pa (P-type semiconductor material layer) and a negative conductive layer Na (N-type semiconductor material layer) formed on the light-emitting body 10a, a reflecting insulating layer 11a formed between the positive conductive layer Pa and the negative conductive layer Na and a light-emitting area Aa formed in the light-emitting body 10a, and the light-emitting body 10a having a bottom material layer Da and a top material layer Ua formed on the bottom material layer Da.

Moreover, the light-emitting body 10a has an Al₂O₃ substrate 100a, a negative GaN conductive layer 101a formed on the Al₂O₃ substrate 100a, and a positive GaN conductive layer 102a formed on the negative GaN conductive layer 101a. The positive conductive layer Pa is formed on the positive GaN conductive layer 102a, the negative conductive layer Na is formed on the negative GaN conductive layer 101a, and the reflecting insulating layer 11a is formed on the negative GaN conductive layer 101a and disposed between the positive conductive layer Pa, the negative conductive layer Na and the positive GaN conductive layer 102a. In addition, the bottom material layer Da is the Al₂O₃ substrate 100a, and the top material layer Ua is composed of the negative GaN conductive layer 101a and the positive GaN conductive layer 102a.

Furthermore, the positive conductive layer Pa has a positive conductive area P1a formed on its top surface, the negative conductive layer Na has a negative conductive area N1a formed on its top surface, and one part of the positive conductive area P1a and one part of the negative conductive area N1a are covered by the reflecting insulating layer 11a. In addition, the reflecting insulating layer 11a is composed of a dielectric layer 110a and a reflecting layer 111a formed on the dielectric layer 110a.

Moreover, the dielectric layer 110a is formed on the negative GaN conductive layer 101a and between the positive electrode layer Pa, the negative electrode layer Na and the positive GaN conductive layer 102a. One part of the positive electrode conductive area P1a of the positive conductive layer Pa and one part of a negative electrode conductive area N1a of the negative conductive layer Na are covered by the dielectric layer 110a. In addition, in the first embodiment, the reflecting layer 111a is only formed on one part of a top surface of the dielectric layer 110a that is over the positive GaN conductive layer 102a.

The step S102 is: referring to FIGS. 2 and 2B, removing a peripheral part of the top material layer Ua (one part of the positive electrode layer Pa and the negative electrode layer Na that are above the peripheral part of the top material layer Ua are also removed) in order to expose an outer area D1a of a top surface of the bottom material layer Da. In addition, after the peripheral part of the top material layer Ua is removed, the top material layer Ua becomes a top material layer Ua′ that is composed of the negative GaN conductive layer 101a′ and the positive GaN conductive layer 102a′. After one part of the positive electrode layer Pa and one part of the negative electrode layer Na are removed, the positive electrode layer Pa becomes a positive electrode layer Pa′ with a positive electrode area P1a′, the negative electrode layer Na becomes a negative electrode layer Na′ with a negative electrode area N1a′ and the light-emitting area Aa is cut into a light-emitting area Aa′.

The step S104 is: referring to FIGS. 2 and 2C, forming an insulating layer 2a on the light-emitting units 1a′. The reflecting insulating layer 2a can be polyimide (PI) or acrylics.

The step S106 is: referring to FIGS. 2 and 2D, removing one part of the insulating layer 2a to form an insulating unit 2a′, the insulating unit 2a′ having at least two first openings 20a′ for exposing one part of the positive conductive layer Pa′ and one part of the negative conductive layer Na′, and the insulating unit being formed around the outer area D1a of the top surface of the bottom material layer Da and formed on a top surface of the reflecting insulating layer 11a.

The step S108 is: referring to FIGS. 2 and 2E, forming a first conductive layer 3a in order to fill the two first openings 20a′ and cover the insulating unit 2a′. In addition, the first conductive layer 3a can be titanium (Ti), wolfram (W), copper (Cu) or their alloy.

The step S110 is: referring to FIGS. 2 and 2F, forming a photoresistant layer Ra on the first conductive layer 3a.

The step S112 is: referring to FIGS. 2 and 2G, removing one part of the photoresistant layer Ra to form at least two second openings R1a′ that are respectively formed above the positive conductive layer Pa′ and the negative conductive layer Na′. One part of the photoresistant layer Ra is removed to form a photoresistant layer Ra′.

The step S114 is: referring to FIGS. 2 and 2H, respectively filling at least two second conductive layers 4a into the two second openings R1a′ in order to form at least two second conductive units. In addition, in the first embodiment, each second conductive unit is composed of at least two conductive layers applied upon each other by electroplating, and the conductive layers are a Nickel layer and a Gold/Tin layer, whereby the Gold/Tin layer is formed on the Nickel layer.

According to different requirements, each second conductive unit is composed of at least three conductive layers applied upon each other by electroplating, and the conductive layers are a Copper layer, a Nickel layer and a Gold/Tin layer, whereby the Nickel layer is formed on the copper layer, and the Gold/Tin layer is formed on the Nickel layer. In other words, the second conductive unit composed of more than two conductive layers applied upon each other is protected in the present invention.

The step S116 is: referring to FIGS. 2 and 2I, removing other photoresistant layer Ra′ and one part of the first conductive layer 3a that is under the other photoresistant layer Ra′, in order to form two first conductive units 3a′.

The step S118 is: referring to FIGS. 2 and 2J, overturning the wafer W and placing the wafer W on a heatproof polymer substrate S.

The step S120 is: referring to FIGS. 2 and 2J, forming a phosphor layer 5a on a bottom side of each light-emitting unit 1a′. In other words, the wafer W is overturned and the phosphor layer 5a is formed on the bottom side of the Al₂O₃ substrate 100a. In addition, the phosphor layer 5a is fluorescent resin that can be formed by mixing silicone and fluorescent powder or mixing epoxy and fluorescent powder.

The step S122 is: referring to FIGS. 2 and 2K, cutting the wafer W along a line X-X of FIG. 2J in order to form a plurality of LED package structure Za. Each LED package structure Za has a phosphor layer 5a′ formed on its bottom side. In addition, each LED package structure Za is electrically disposed on a PCB (Printed Circuit Board) B via at least two solder balls Ba. Light beams La generated from the light-generating area Aa′ of each LED package structure Za pass through the phosphor layer 5a′ in order to provide illumination. Furthermore, one part of the light beams generated from the light-generating area Aa′ is projected downwards and is reflected by the positive conductive layer Pa′, the negative conductive layer Na′ and the reflecting layer 111a in order to generate upward projecting light.

Therefore, referring to FIG. 2K, the first embodiment of the present invention provides a wafer level LED package structure for increasing light-emitting efficiency, including: a light-emitting unit 1a′, an insulating unit 2a′, at least two first conductive unit 3a′, and at least two second conductive unit (at least two second conductive layers 4a).

The light-emitting unit 1a′ has a light-emitting body 10a′, a positive conductive layer Pa′ and a negative conductive layer Na′ formed on the light-emitting body 10a′, a reflecting insulating layer 11a′ formed between the positive conductive layer Pa′ and the negative conductive layer Na′, and a light-emitting area Aa′ formed in the light-emitting body 10a′. The light-emitting body 10a′ has a bottom material layer Da and a top material layer Ua′ formed on the bottom material layer Da.

In addition, the light-emitting body 10a′ has an Al₂O₃ substrate 100a′, a negative GaN conductive layer 101a′ formed on the Al₂O₃ substrate 100a′, and a positive GaN conductive layer 102a′ formed on the negative GaN conductive layer 101a′. The positive conductive layer Pa′ is formed on the positive GaN conductive layer 102a′, the negative conductive layer Na′ is formed on the negative GaN conductive layer 101a′, and the reflecting insulating layer 11a′ is formed on the negative GaN conductive layer 101a′ and disposed between the positive conductive layer Pa′, the negative conductive layer Na′ and the positive GaN conductive layer 102a′.

Moreover, the positive conductive layer Pa′ has a positive conductive area P1a′ formed on its top surface, the negative conductive layer Na′ has a negative conductive area N1a′ formed on its top surface, and one part of the positive conductive area P1a′ and one part of the negative conductive area N1a′ are covered by the reflecting insulating layer 11a. In addition, the reflecting insulating layer 11a is composed of a dielectric layer 110a and a reflecting layer 111a formed on the dielectric layer 110a. The top material layer Ua′ is composed of the negative GaN conductive layer 101a′ and the positive GaN conductive layer 102a′.

Furthermore, the dielectric layer 110a is formed on the negative GaN conductive layer 101a′ and between the positive electrode layer Pa′, the negative electrode layer Na′ and the positive GaN conductive layer 102a′. One part of the positive electrode conductive area P1a′ of the positive conductive layer Pa′ and one part of a negative electrode conductive area N1a′ of the negative conductive layer Na′ are covered by the dielectric layer 110a. In addition, in the first embodiment, the reflecting layer 111a is only formed on one part of a top surface of the dielectric layer 110a that is over the positive GaN conductive layer 102a′.

In addition, the insulating unit 2a′ is formed around an outer area D1a of a top surface of the bottom material layer Da and formed on a top surface of the reflecting insulating layer 11a. One first conductive unit 3a′ is formed on one part of the positive conductive layer Pa′ and on one part of the insulating unit 2a′, and another first conductive unit 3a′ is formed on one part of the negative conductive layer Na′ and on one part of the insulating unit 2a′. The two second conductive units (the two second conductive layers 4a) are respectively formed on the two first conductive units 3a′. Furthermore, the phosphor layer 5a′ formed on the bottom side of the Al₂O₃ substrate 100a of the light-emitting unit 1a′ mates with the light beams La generated from light-emitting area Aa′ in order to provide white light.

Referring to FIG. 2L, each LED package structure Za is electrically disposed on a PCB (Printed Circuit Board) B via at least two layers of solder glue Ba′.

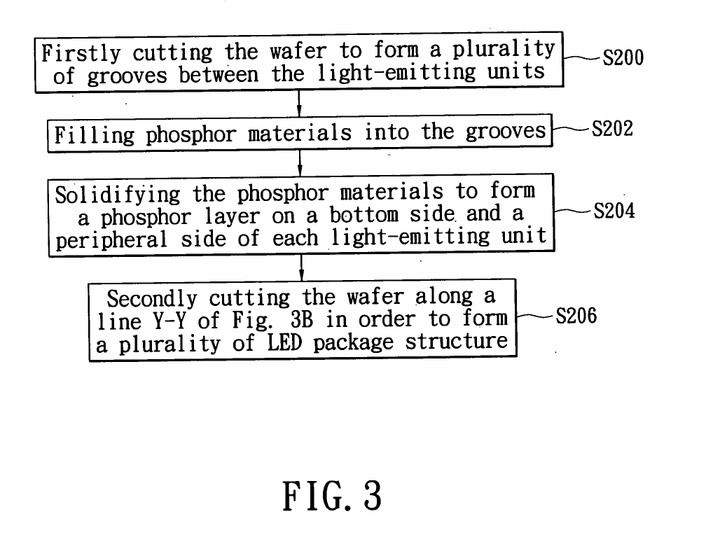

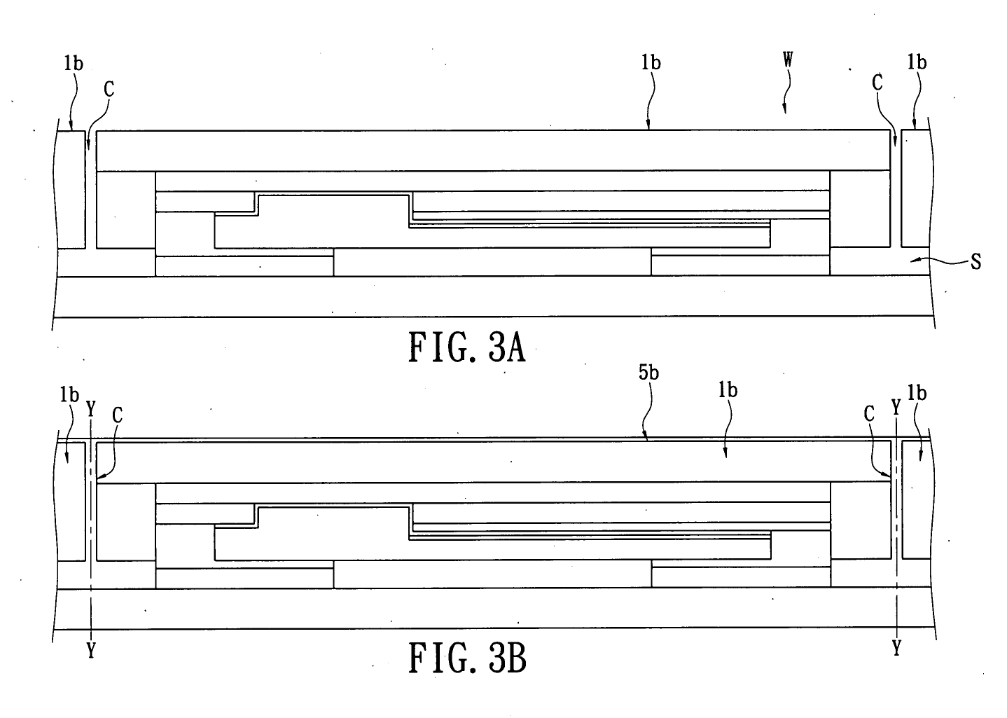

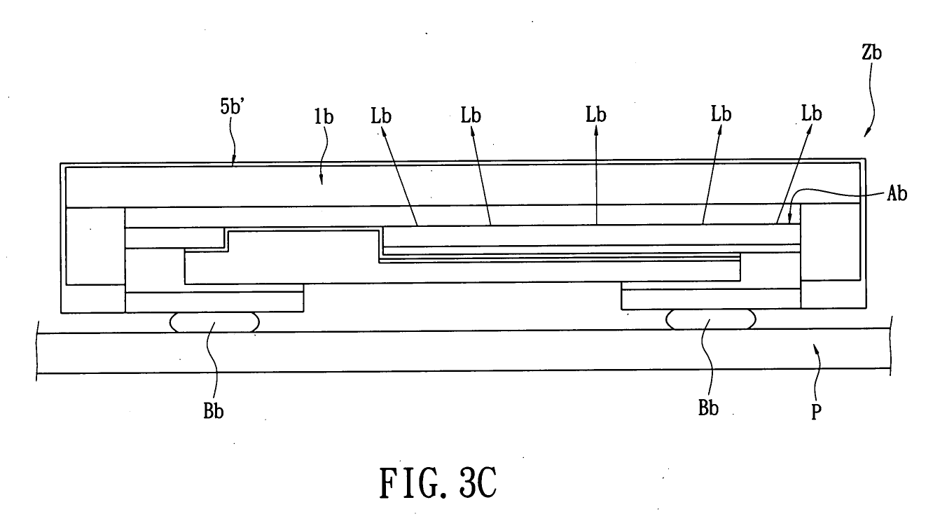

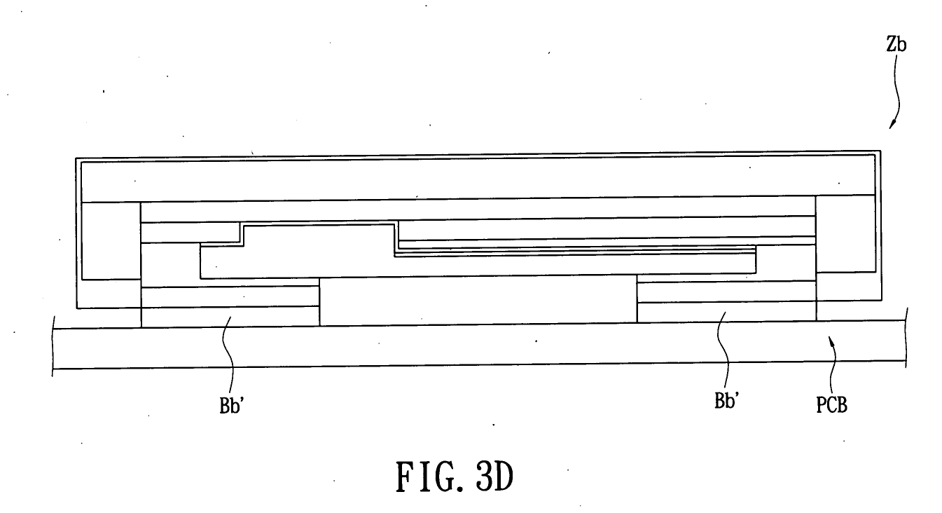

Referring to FIGS. 3 and 3A to 3C, the difference between the second embodiment and the first embodiment is that: after the step of overturning the wafer W and placing the wafer W on a heatproof polymer substrate S, the method of the second embodiment further includes following steps:

The step S200 is: referring to FIGS. 3 and 3A, firstly cutting the wafer W to form a plurality of grooves C between the light-emitting units 1b.

The step S202 is: referring to FIGS. 3 and 3B, filling phosphor materials (not shown) into the grooves C. In addition, the phosphor materials are fluorescent resin that can be formed by mixing silicone and fluorescent powder or mixing epoxy and fluorescent powder.

The step S204 is: referring to FIGS. 3 and 3B, solidifying the phosphor materials to form a phosphor layer 5b on a bottom side and a peripheral side of each light-emitting unit 1b.

The step S206 is: referring to FIGS. 3 and 3C, secondly cutting the wafer W along a line Y-Y of FIG. 3B in order to form a plurality of LED package structure Zb. Each LED package structure Zb has a phosphor layer 5b′ formed on a bottom side and a peripheral side of the light-emitting unit 1b or on a bottom side and a peripheral side of each LED package structure Zb. In addition, each LED package structure Zb is electrically disposed on a PCB (Printed Circuit Board) B via at least two solder balls Bb. Light beams Lb generated from the light-generating area Ab of each LED package structure Zb pass through the phosphor layer 5b′ in order to provide illumination.

Therefore, referring to FIG. 3C, the difference between the second embodiment and the first embodiment is that: the phosphor layer 5b′ is formed on the bottom side and the peripheral side of the light-emitting unit 1b or on the bottom side and the peripheral side of each LED package structure Zb in order to mate with the light beams Lb generated from light-emitting area Ab for providing white light.

Referring to FIG. 3D, each LED package structure Zb is electrically disposed on a PCB (Printed Circuit Board) B via at least two layers of solder glue Bb′.

In conclusion, the present invention has the following advantages:

1. With regards to the first embodiment, the phosphor layer 5a′ formed on the bottom side of the Al₂O₃ substrate 100a mates with the light beams La generated from light-emitting area Aa′ in order to provide white light. With regards to the second embodiment, the phosphor layer 5b′ is formed on the bottom side and the peripheral side of the light-emitting unit 1b in order to mate with the light beams Lb generated from light-emitting area Ab for providing white light.

2. The present invention does not need to use reflecting layer, the transparent package body and the wires as shown in prior art. Hence, the manufacturing cost and manufacturing time of the present invention are decreased.

3. The present invention uses the insulating unit in order to increase the thickness of the reflecting insulating layer, so that the short circuit does not occur easily between the lateral side of the positive GaN conductive layer and the negative GaN conductive layer.

Although the present invention has been described with reference to the preferred best molds thereof, it will be understood that the present invention is not limited to the details thereof. Various substitutions and modifications have been suggested in the foregoing description, and others will occur to those of ordinary skill in the art. Therefore, all such substitutions and modifications are intended to be embraced within the scope of the present invention as defined in the appended claims.

What is claimed is:

1. A wafer level LED package structure for increasing light-emitting efficiency, comprising:
a light-emitting unit having a light-emitting body, a positive conductive layer and a negative conductive layer formed on the light-emitting body, a reflecting insulating layer formed between the positive conductive layer and the negative conductive layer, and a light-emitting area formed in the light-emitting body, wherein the light-emitting body has a bottom material layer and a top material layer formed on the bottom material layer;
an insulating unit formed around an outer area of a top surface of the bottom material layer and formed on a top surface of the reflecting insulating layer;
at least two first conductive units, wherein one first conductive unit is formed on one part of the positive conductive layer and on one part of the insulating unit, and another first conductive unit is formed on one part of the negative conductive layer and on one part of the insulating unit; and
at least two second conductive units respectively formed on the two first conductive units.

2. The wafer level LED package structure as claimed in claim 1, wherein the light-emitting body has an Al₂O₃ substrate, a negative GaN conductive layer formed on the Al₂O₃ substrate, and a positive GaN conductive layer formed on the negative GaN conductive layer; the positive conductive layer is formed on the positive GaN conductive layer, the negative conductive layer is formed on the negative GaN conductive layer, and the reflecting insulating layer is formed on the negative GaN conductive layer and disposed between the positive conductive layer, the negative conductive layer and the positive GaN conductive layer, wherein the bottom material layer is the Al₂O₃ substrate, and the top material layer is composed of the negative GaN conductive layer and the positive GaN conductive layer.

3. The wafer level LED package structure as claimed in claim 2, wherein the reflecting insulating layer is composed of a dielectric layer and a reflecting layer formed on the dielectric layer, the dielectric layer is formed on the negative GaN conductive layer and between the positive electrode layer, the negative electrode layer and the positive GaN conductive layer, one part of a positive electrode conductive area of the positive conductive layer and one part of a negative electrode conductive area of the negative conductive layer are covered by the dielectric layer, and the reflecting layer is only formed on one part of a top surface of the dielectric layer that is over the positive GaN conductive layer.

4. The wafer level LED package structure as claimed in claim 1, wherein the reflecting insulating layer is composed of a dielectric layer and a reflecting layer formed on the dielectric layer.

5. The wafer level LED package structure as claimed in claim 1, wherein the reflecting insulating layer is polyimide or acrylics.

6. The wafer level LED package structure as claimed in claim 1, wherein the positive conductive layer has a positive conductive area formed on a top surface thereof, the negative conductive layer has a negative conductive area formed on a top surface thereof, and one part of the positive conductive area and one part of the negative conductive area are covered by the reflecting insulating layer.

7. The wafer level LED package structure as claimed in claim 1, wherein each second conductive unit is composed of at least two conductive layers applied upon each other by electroplating, and the conductive layers are a Nickel layer and a Gold/Tin layer, whereby the Gold/Tin layer is formed on the Nickel layer.

8. The wafer level LED package structure as claimed in claim 1, wherein each second conductive unit is composed of at least three conductive layers applied upon each other by electroplating, and the conductive layers are a Copper layer, a Nickel layer and a Gold/Tin layer, whereby the Nickel layer is formed on the copper layer, and the Gold/Tin layer is formed on the Nickel layer.

9. The wafer level LED package structure as claimed in claim 1, further comprising: a phosphor layer formed on a bottom side of the light-emitting unit or on a bottom side and a peripheral side of the light-emitting unit.

10. A method for making a wafer level LED package structure for increasing light-emitting efficiency, comprising:
providing a wafer having a plurality of light-emitting units, wherein each light-emitting unit has a light-emitting body, a positive conductive layer and a negative conductive layer formed on the light-emitting body, a reflecting insulating layer formed between the positive conductive layer and the negative conductive layer, and a light-emitting area formed in the light-emitting body, wherein the light-emitting body has a bottom material layer and a top material layer formed on the bottom material layer;
removing a peripheral part of the top material layer in order to expose an outer area of a top surface of the bottom material layer;
forming an insulating layer on the light-emitting units;
removing one part of the insulating layer to form an insulating unit, wherein the insulating unit has at least two first openings for exposing one part of the positive conductive layer and one part of the negative conductive layer, and the insulating unit is formed around the outer area of the top surface of the bottom material layer and formed on a top surface of the reflecting insulating layer;
forming a first conductive layer in order to fill the two first openings and cover the insulating unit;
forming a photoresistant layer on the first conductive layer;
removing one part of the photoresistant layer to form at least two second openings that are respectively formed above the positive conductive layer and the negative conductive layer;
respectively filling at least two second conductive layers into the two second openings in order to form at least two second conductive units; and
removing other photoresistant layer and one part of the first conductive layer that is under the other photoresistant layer, in order to form two first conductive units.

11. The method as claimed in claim 10, wherein the light-emitting body has an Al₂O₃ substrate, a negative GaN conductive layer formed on the Al₂O₃ substrate, and a positive GaN conductive layer formed on the negative GaN conductive layer; the positive conductive layer is formed on the positive GaN conductive layer, the negative conductive layer is formed on the negative GaN conductive layer, and the reflecting insulating layer is formed on the negative GaN conductive layer and disposed between the positive conductive layer, the negative conductive layer and the positive GaN conductive layer, wherein the bottom material layer is the Al₂O₃ substrate, and the top material layer is composed of the negative GaN conductive layer and the positive GaN conductive layer.

12. The method as claimed in claim 11, wherein the reflecting insulating layer is composed of a dielectric layer and a reflecting layer formed on the dielectric layer, the dielectric layer is formed on the negative GaN conductive layer and between the positive electrode layer, the negative electrode layer and the positive GaN conductive layer, one part of a positive electrode conductive area of the positive conductive layer and one part of a negative electrode conductive area of the negative conductive layer are covered by the dielectric layer, and the reflecting layer is only formed on one part of a top surface of the dielectric layer that is over the positive GaN conductive layer.

13. The method as claimed in claim 10, wherein the reflecting insulating layer is composed of a dielectric layer and a reflecting layer formed on the dielectric layer.

14. The method as claimed in claim 10, wherein the reflecting insulating layer is polyimide or acrylics.

15. The method as claimed in claim 10, wherein the positive conductive layer has a positive conductive area formed on its top surface, the negative conductive layer has a negative conductive area formed on its top surface, and one part of the positive conductive area and one part of the negative conductive area are covered by the reflecting insulating layer.

16. The method as claimed in claim 10, wherein each second conductive unit is composed of at least two conductive layers applied upon each other by electroplating, and the conductive layers are a Nickel layer and a Gold/Tin layer, whereby the Gold/Tin layer is formed on the Nickel layer.

17. The method as claimed in claim 10, wherein each second conductive unit is composed of at least three conductive layers applied upon each other by electroplating, and the conductive layers are a Copper layer, a Nickel layer and a Gold/Tin layer, whereby the Nickel layer is formed on the copper layer, and the Gold/Tin layer is formed on the Nickel layer.

18. The method as claimed in claim 10, wherein after the step of forming the two first conductive units, the method further comprises:
overturning the wafer and placing the wafer on a heatproof polymer substrate;
forming a phosphor layer on a bottom side of each light-emitting unit; and
cutting the wafer in order to form a plurality of LED package structure.

19. The method as claimed in claim 10, wherein after the step of forming the two first conductive units, the method further comprises:
overturning the wafer and placing the wafer on a heatproof polymer substrate;
firstly cutting the wafer to form a plurality of grooves between the light-emitting units;
filling phosphor materials into the grooves;
solidifying the phosphor materials to form a phosphor layer on a bottom side and a peripheral side of each light-emitting unit; and
secondly cutting the wafer in order to form a plurality of LED package structure.
